(19) United States
(12) Patent Application Publication
(10) Pub. No.: US 2015/0046723 A1
(43) Pub. Date: Feb. 12, 2015

(54) SENSE-AMPLIFIER DRIVING DEVICE AND SEMICONDUCTOR DEVICE INCLUDING THE SAME

(71) Applicant: SK hynix Inc., Icheon-si (KR)

(72) Inventors: Sang Il PARK, Suwon-si (KR); Sang Kwon LEE, Yongin-si (KR)

(73) Assignee: SK hynix Inc., Icheon-si (KR)

(21) Appl. No.: 14/097,490

(22) Filed: Dec. 5, 2013

(30) Foreign Application Priority Data
Aug. 7, 2013 (KR) 10-2013-0093667

(51) Int. Cl. G11C 11/4074; G06F 1/26

(52) U.S. Cl. CPC G11C 11/4074; G06F 1/26
USPC 713/300; 365/189.11

(57) ABSTRACT

A sense-amplifier driving device includes: a power-supply driving unit configured to respectively provide a first pull-up voltage and a first pull-down voltage to a pull-up power line and a pull-down power line during a first over-driving time section, and provide the first pull-up voltage to the pull-up power line during a second over-driving time section; an over-driving controller configured to provide a second pull-down voltage lower than the first pull-down voltage to the pull-down power line during the second over-driving time section; and a drive-signal generator configured to generate a drive signal activated for the first and second over-driving time sections so as to control driving of the power-supply driving unit.

### CROSS-REFERENCE TO RELATED APPLICATION

This application claims priority based upon Korean patent application No. 10-2013-0093667, filed on Aug. 7, 2013, the disclosure of which is hereby incorporated in its entirety by reference herein.

### BACKGROUND

Embodiments of the present invention generally relate to a sense-amplifier driving device and a semiconductor device including the same, and more particularly to a technology for improving refresh characteristics of the semiconductor device.

With the increasing integration degree of semiconductor memory devices, semiconductor memory devices have also been continuously improved to increase the operation speed. In order to increase operation speeds of semiconductor memory devices, synchronous memory devices capable of operating by synchronizing with an external clock of a memory chip have been recently proposed and developed.

A representative example of a synchronous memory device is a single data rate (SDR) synchronous memory device that is synchronized with a rising edge of an external clock of a memory device such that one data piece can be input and/or output at one data pin during one period of the clock.

However, the SDR synchronous memory device has difficulty in satisfying a high-speed operation of the system. In order to solve the problem of the SDR synchronous memory device, a double data rate (DDR) synchronous memory device capable of processing two data pieces during one clock period has been proposed.

Two contiguous data pieces are input and output through respective data input/output (I/O) pins of the DDR synchronous memory device, such that the two contiguous data pieces are synchronized with a rising edge and a falling edge of an external input clock. Therefore, although a clock frequency of the DDR synchronous memory device is not increased, the DDR synchronous memory device may have a bandwidth that is at least two times larger than that of the SDR synchronous memory device, such that the DDR synchronous memory device can operate at a higher speed than the SDR synchronous memory device.

Meanwhile, a Dynamic Random Access Memory (DRAM) from among semiconductor memory devices is a representative volatile memory. A memory cell of the DRAM is comprised of a cell transistor and a cell capacitor.

In this case, the cell transistor controls accessing the cell capacitor, and the cell capacitor stores electric charges corresponding to data. That is, the stored data is classified into high-level data and low-level data according to the amount of electric charges stored in the cell capacitor.

Since electric charges are applied or leaked to the cell capacitor of the memory cell of the DRAM by a leakage component, the corresponding data should be periodically stored again in the cell capacitor. As described above, the above periodic storing operation for correctly maintaining desired data is referred to as a refresh operation.

A memory cell of the DRAM is activated in an active mode. A bit-line sense-amplifier (sense-amp) circuit is configured to sense/amplify data received from the activated memory cell, and re-transmits the amplified data to a memory cell.

In addition, the memory cell is deactivated in a precharge mode and at the same time data stored in the memory cell is maintained. That is, the refresh operation may represent a technology for repeatedly performing the active and precharge operations at intervals of a predetermined time.

However, assuming that an external power-supply voltage (VDD) level decreases as in LPDDR4 specification, a core voltage (Vcore) lower than the power-supply voltage (VDD) is used as an internal voltage, resulting in reduction of a data retention time. Therefore, refresh characteristics of the DRAM are gradually deteriorated in proportion to the reducing power-supply voltage (VDD).

### BRIEF SUMMARY OF THE INVENTION

Various embodiments of the present invention may be directed to providing a sense-amplifier driving device and a semiconductor device including the same that substantially obviates one or more problems due to limitations and disadvantages of the related art.

The embodiments of the present invention may relate to a technology for improving refresh characteristics of a semiconductor device so as to increase a data retention time.

In accordance with an embodiment of the present invention, a sense-amplifier driving device includes: a power-supply driving unit configured to respectively provide a first pull-up voltage and a first pull-down voltage to a pull-up power line and a pull-down power line during a first over-driving time section, and provide the first pull-up voltage to the pull-up power line during a second over-driving time section; an over-driving controller configured to provide a second pull-down voltage lower than the first pull-down voltage to the pull-down power line during the second over-driving time section; and a drive-signal generator configured to generate a drive signal activated for the first and second over-driving time sections so as to control driving of the power-supply driving unit.

In accordance with an embodiment of the present invention, a semiconductor device includes: a memory cell in which a read or write operation of data is achieved; a sense-amplifier configured to sense and amplify the data in response to a voltage applied to a pull-up power line and a pull-down power line; and a sense-amplifier driving unit configured to provide a first pull-up voltage and a second pull-down voltage to the pull-up power line and the pull-down power line during a first over-driving time section, and configured to provide a second pull-down voltage lower than the first pull-up voltage and the first pull-down voltage to the pull-up power line and the pull-down power line during a second over-driving time section.

In accordance with an embodiment of the present invention, a sense-amplifier driving device includes: an over-driving controller configured to provide a pull-down voltage lower than a ground voltage to a pull-down power line of a sense-amplifier when a pull-down drive signal is activated in an over-driving time section; and a drive-signal generator configured to generate the pull-down drive signal activated for the over-driving time section so as to control driving of the over-driving controller.

In accordance with an embodiment of the present invention, a system includes: a processor; a memory controller configured to receive a request and data from the processor; and a memory device configured to receive a memory controller request and the data from the memory controller, wherein the memory device includes a sense-amplifier driving device including: a power-supply driving unit configured to respectively provide a first pull-up voltage and a first pull-down voltage to a pull-up power line and a pull-down power line during a first over-driving time section, and provide the first pull-up voltage to the pull-up power line during a second over-driving time section; an over-driving controller configured to provide a second pull-down voltage lower than the first pull-down voltage to the pull-down power line during the second over-driving time section; and a drive-signal generator configured to generate a drive signal activated for the first and second over-driving time sections so as to control driving of the power-supply driving unit.

In accordance with an embodiment of the present invention, a system includes: a processor; a chipset configured to couple with the processor; a controller configured to receive a request provided from the processor through the chipset; a memory device configured to receive a memory controller request and the data from the controller; and an I/O device configured to couple with the chipset, wherein the memory device includes a sense-amplifier driving device including: a power-supply driving unit configured to respectively provide a first pull-up voltage and a first pull-down voltage to a pull-up power line and a pull-down power line during a first over-driving time section, and provide the first pull-up voltage to the pull-up power line during a second over-driving time section; an over-driving controller configured to provide a second pull-down voltage lower than the first pull-down voltage to the pull-down power line during the second over-driving time section; and a drive-signal generator configured to generate a drive signal activated for the first and second over-driving time sections so as to control driving of the power-supply driving unit.

It is to be understood that both the foregoing general description and the following detailed description of the present invention are exemplary and explanatory and are intended to provide further explanation of the invention as claimed.

### BRIEF DESCRIPTION OF THE DRAWINGS

The above and other features and advantages of the present invention will become readily apparent by reference to the following detailed description when considered in conjunction with the accompanying drawings wherein:

FIG. 1 is a block diagram illustrating a semiconductor device according to an embodiment.

FIG. 2 is a detailed circuit diagram illustrating a drive-signal generator shown in FIG. 1.

FIG. 3 is a detailed circuit diagram illustrating a power-supply driving unit and an over-driving controller shown in FIG. 1.

FIG. 4 is a timing diagram illustrating operations of a power-supply driving unit and an over-driving controller shown in FIG. 3.

FIG. 5 illustrates a block diagram of a system employing a semiconductor device in accordance with embodiments of the present invention.

### DETAILED DESCRIPTION

Reference will now be made in detail to various embodiments, examples of which are illustrated in the accompanying drawings. Wherever possible, the same reference numbers will be used throughout the drawings to refer to the same or like parts.

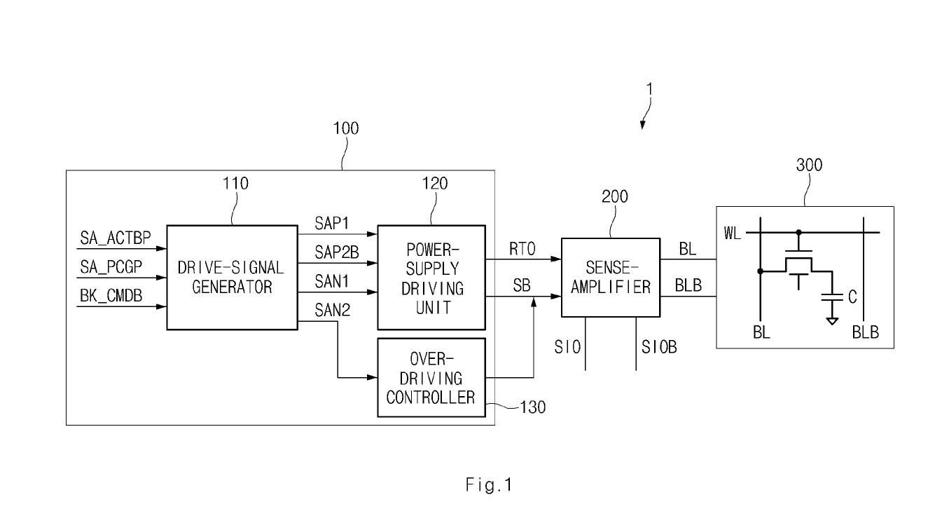

FIG. 1 is a block diagram illustrating a semiconductor device according to an embodiment.

Referring to FIG. 1, data stored in a semiconductor device 1 according to an embodiment is classified into a logic high level (H) denoted by ‘1’ and a logic low level (L) denoted by ‘0’. In this case, data values may be differentially classified according to a voltage level and a current value. In the case of binary data, a high level is defined as a high voltage and a low level is defined as a low voltage lower than the high-level voltage.

Referring to FIG. 1, the semiconductor device 1 may include a sense-amplifier driving device 100, a sense-amplifier 200, and a memory cell 300. In this case, the sense-amplifier driving device 100 may include a drive-signal generator 110, a power-supply driving unit 120, and an over-driving controller 130.

The drive-signal generator 110 may generate pull-up drive signals (SAP1, SAP2B) and pull-down drive signals (SAN1, SAN2) according to an active signal (SA_ACTBP), a precharge signal (SA_PCGP), and an internal command signal (BK_CMDB). In this case, the pull-up drive signals (SAP1, SAP2B) and the pull-down drive signals (SAN1, SAN2) are activated according to the active signal (SA_ACTBP), the precharge signal (SA_PCGP) and the internal command signal (BK_CMDB) during their reserved time sections.

The active signal (SA_ACTBP) is activated after the lapse of a reserved time from a start time of an active command, and the precharge signal (SA_PCGP) is activated after the lapse of a reserved time from a start time of a precharge command.

The power-supply driving unit 120 may provide a power-supply signal to a pull-up power line (RTO) and a pull-down power line (SB) coupled to the sense-amplifier 200 according to the pull-up drive signals (SAP1, SAP2B) and the pull-down drive signal (SAN1). In addition, the over-driving controller 130 may control an over-driving operation of the pull-down power line (SB) in response to a pull-down drive signal (SAN2).

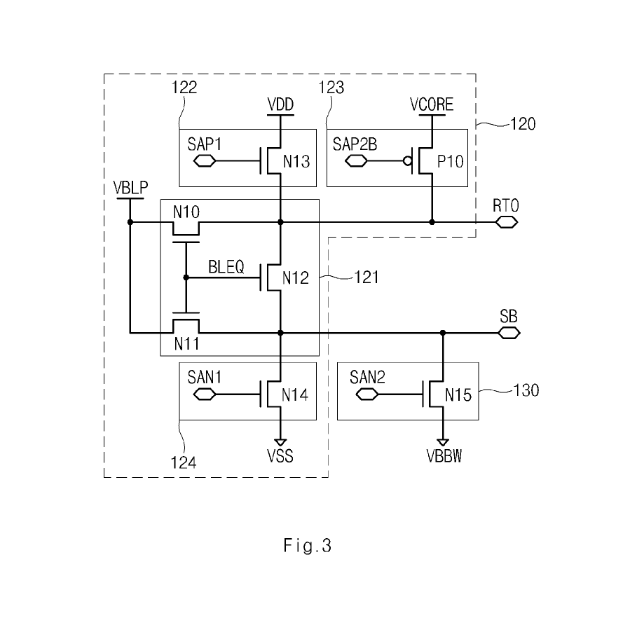

Referring to FIG. 3 as well, the power-supply driving unit 120 may drive the power-up power line (RTO) at a power-supply voltage (VDD) level (i.e., a first pull-up voltage) or a core voltage (VCORE) level (i.e., a second pull-up voltage level) in response to the pull-up drive signals (SAP1, SAP2B). In addition, the power-supply driving unit 120 may drive the pull-down power line (SB) at a ground voltage (VSS) (i.e., a first pull-down voltage) in response to the pull-down drive signal (SAN1). In addition, the pull-up power line (RTO) and the pull-down power line (SB) may be precharged with a precharge voltage (VBLP) in response to a precharge signal (BLEQ).

The over-driving controller 130 may drive the pull-down power line (SB) at a back-bias voltage (VBBW) (i.e., a second pull-down voltage) in response to the pull-down drive signal (SAN2).

The sense-amplifier 200 may operate in response to a drive power-supply signal applied to the pull-up power line (RTO) and the pull-down power line (SB). The sense-amplifier 200 may sense and amplify data received from the memory cell 300 through a pair of bit lines (BL, BLB), and output the amplified data to the sensing lines (SIO, SIOB).

The above-mentioned sense-amplifier driving device 100 may provide the core voltage (VCORE) to the pull-up power line (RTO) and provide a ground voltage (VSS) to the pull-down power line (SB) during the active mode. On the other hand, the sense-amplifier driving device 100 may provide a power-supply voltage (VDD) higher than the core voltage (VCORE) to the pull-up power line (RTO) during an over-driving mode, and may provide a back-bias voltage (VBBW) lower than the ground voltage (VSS) to the pull-down power line (SB) during the over-driving mode. For reference, the sense-amplifier driving device 100 may also provide the power-supply voltage (VDD) to the pull-up power line (RTO) during an initial reserved time interval of the active mode.

In addition, the sense-amplifier driving device 100 may provide a bit-line precharge voltage (VBLP) to the pull-up power line (RTO) and the pull-down power line (SB) after the memory cell 300 has been deactivated in the precharge mode. During the precharge mode, the memory cell 300 may be deactivated and maintain stored data. In this case, a pair of bit lines (BL, BLB) may be precharged with the bit-line precharge voltage (VBLP).

The semiconductor device 1 according to an embodiment may perform the over-driving operation within a developing section of the pair of bit lines (BL, BLB) so as to improve a RAS to CAS Delay time (tRCD). The semiconductor device 10 according to an embodiment may enable the sense-amplifier driving device 100 to perform the over-driving operation during a predetermined time, prior to deactivation of word lines (memory cell).

For example, it is assumed that high-level data is stored in the memory cell 300, and the sense-amplifier 200 amplifies the high-level data, such that the amplified data is transferred to the memory cell 300. Prior to deactivation of the memory cell 300, the memory cell 300 may receive the power-supply voltage (VDD) higher than the core voltage (VCORE) and the back-bias voltage (VBBW) lower than the ground voltage (VSS). Accordingly, a data retention time is improved under the condition that the memory cell 300 is deactivated.

In a data write mode, the memory cell 300 is activated such that data (WRITE DATA) is transferred to the pair of bit lines (BL, BLB) through the sensing lines (SIO, SIOB). In this case, the sense-amplifier 200 may sense and amplify the write data of the pair of bit lines (BL, BLB), and output the amplified write data to the memory cell 300.

For example, it is assumed that high-level write data is applied to the memory cell 300. The sense-amplifier 200 may provide the write data to the memory cell 300 at the core voltage (VCORE).

Thereafter, the semiconductor device 1 may receive a power-supply voltage (VDD) higher than the core voltage (VCORE) and a back-bias voltage (VBBW) lower than the ground voltage (VSS) during the precharge mode, prior to deactivation of the memory cell 300. Accordingly, the semiconductor device 1 can reduce a specific time (tWR) for receiving the precharge command after the lapse of a start time of a data write command. Particularly, a data retention time is improved under the condition that the memory cell 300 is deactivated.

Activation of the memory cell 300 may represent that a cell capacitor C is electrically coupled to a true bit-line (BL) because a cell transistor T is turned on by a control voltage received through a word line (WL). In addition, deactivation of the memory cell 300 may represent that the cell transistor T is turned off.

In addition, the semiconductor device 1 may enter the corresponding operation mode upon receiving the active command, the precharge command, or the write command, etc. Mainly, the semiconductor device 1 may substantially enter the corresponding operation mode after lapse of a reserved time starting from an input time of the command signal.

In addition, the semiconductor device 1 may receive a data write command or a data read command during a predetermined time between the active command and the precharge command, such that the semiconductor device 1 can perform the data write operation or the data read operation.

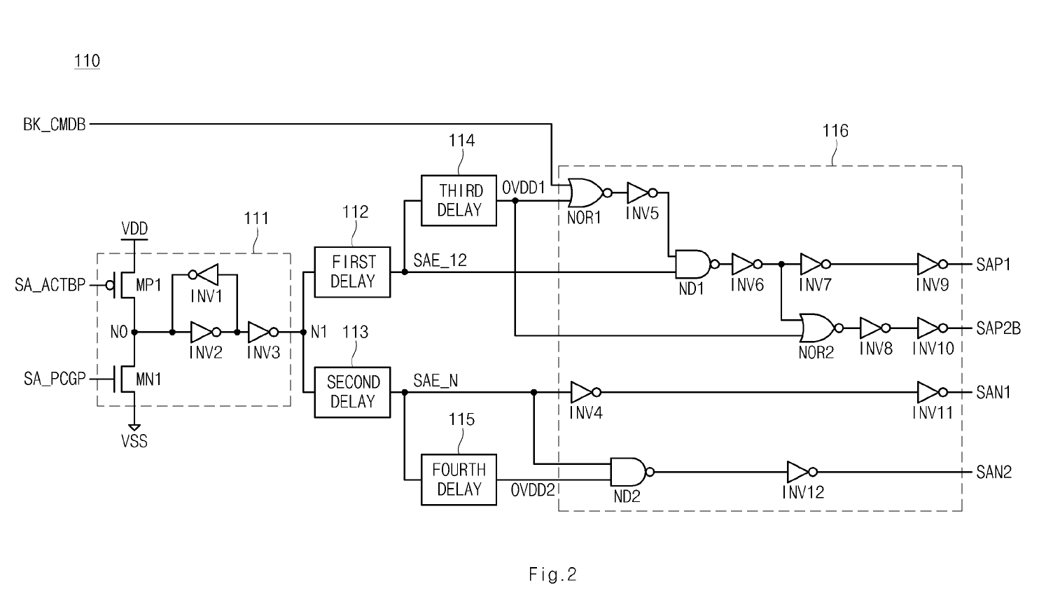

FIG. 2 is a detailed circuit diagram illustrating the drive-signal generator 110 shown in FIG. 1.

Referring to FIG. 2, an internal command signal (BK_CMDB) is obtained when the active signal is buffered and inverted. The active signal (SA_ACTBP) is pulsed at a low level after lapse of a reserved time starting from an input time of the active command. The precharge signal (SA_PCGP) is pulsed at a high level after lapse of a reserved time starting from an input time of the precharge command. From the viewpoint of an input time of the precharge command, the internal command signal (BK_CMDB) may be activated earlier than the precharge signal (SA_PCGP).

The drive-signal generator 110 may include a control signal generator 111, a plurality of delay units (112˜115), and a signal combination unit 116. In this case, the control signal generator 111 may pull up or down the node N0 in response to the active signal (SA_ACTBP) and the precharge signal (SA_PCGP), and may decide a voltage level of the node N1.

The drive-signal generator 110 may include a PMOS transistor MP1, an NMOS transistor MN1, and a plurality of inverters (INV1˜INV3). In this case, the PMOS transistor MP1 and the NMOS transistor MN1 are coupled in series between the power-supply voltage (VDD) input terminal and the ground voltage (VSS) input terminal. The PMOS transistor MP1 may receive the active signal (SA_ACTBP) through a gate terminal, and the NMOS transistor MN1 may receive the precharge signal (SA_PCGP) through a gate terminal.

Inverters (INV1, INV2) interconnected by a latch structure may latch an output signal of the node N0. The inverter IV3 may invert the output signal of the inverter IV2, and output the inverted signal to the node N1.

A plurality of delay units (112˜115) may delay the output signal of the node N1 so as to output a delay signal (SAE_12), a delay signal (SAE_N), and the delay signals (OVDD1, OVDD2). The delay unit 112 (i.e., FIRST DELAY) and the other delay unit 113 (i.e., SECOND DELAY) may have a delay value for adjusting a difference in activation time between a pull-up drive signal (SAP1) and a pull-down drive signal (SAN1) during an initial over-driving time section. In addition, the delay unit 114 (i.e., THIRD DELAY)and the other delay unit 115 (i.e., FOURTH DELAY) may have a delay value for adjusting a difference in over-driving time between a pull-up drive signal (SAP2B) and a pull-down drive signal (SAN2) during the over-driving time section.

The signal combination unit 116 may combine a delay signal (SAE_12), a delay signal (SAE_N), and other delay signals (OVDD1, OVDD2), such that the signal combination unit 116 may output the pull-up drive signals (SAP1, SAP2B) and the pull-down drive signals SAN1, SAN2 activated in a reserved time section.

The signal combination unit 116 includes a plurality of NOR gates (NOR1, NOR2), a plurality of NAND gates (ND1, ND2), and a plurality of inverters (INV4˜INV12). The NOR gate NOR1 may perform a NOR operation between an internal command signal (BK_CMDB) and a delay signal (OVDD1). The inverter INV5 may invert the output signal of the NOR gate NOR1. The NAND gate ND1 may perform a NAND operation between the output signal of the inverter INV5 and the output of the delay signal (SAE_12). The inverters (INV6, INV7, INV9) may invert and delay the output signal of the NAND gate ND1 so as to output a pull-up drive signal (SAP1).

The NOR gate NOR2 may perform a NOR operation between the output of the inverter INV6 and the delay signal (OVDD1). The inverters (INV8, INV10) may perform non-invert delaying of the output signal of the NOR gate NOR2 so as to output a pull-up drive signal (SAP2B). In addition, the inverters (INV4, INV11) may perform non-invert delaying of the delay signal (SAE_N) so as to output a pull-down drive signal (SAN1). The NAND gate ND2 may perform a NAND operation between the delay signal (SAE_N) and the delay signal (OVDD2). The inverter INV12 may perform non-invert delaying of the output signal of the NAND gate ND2 so as to output a pull-down drive signal (SAN2).

FIG. 3 is a detailed circuit diagram illustrating the power-supply driving unit 120 and the over-driving controller 130 shown in FIG. 1.

Referring to FIG. 3, the power-supply driving unit 120 may include a precharge driver 121, pull-up drivers (122, 123), and a pull-down driver 124.

In this case, the precharge driver 121 may provide a precharge voltage (VBLP) to a pull-up power line (RTO) and a pull-down power line (SB) upon receiving the precharge signal (BLEQ) in the precharge mode. The precharge driver 121 may include a plurality of NMOS transistors (N10˜N12) commonly coupled at their gate terminals.

The NMOS transistor N10 may be coupled between the precharge voltage (VBLP) input terminal and the pull-up power line (RTO). The NMOS transistor N11 may be coupled between the precharge voltage (VBLP) input terminal and the pull-down power line (SB). The NMOS transistor N12 may be coupled between the pull-up power line (RTO) and the pull-down power line (SB).

If the pull-up drive signal (SAP1) is activated during the over-driving time section, the pull-up driver 122 may provide a power-supply voltage (VDD) acting as an over-driving voltage to the pull-up power line (RTO). The pull-up driver 122 may include an NMOS transistor N13. The NMOS transistor N13 may be coupled between the power-supply voltage (VDD) input terminal and the pull-up power line (RTO) so as to receive the pull-up drive signal (SAP1) through a gate terminal.

If the pull-up drive signal (SAP2B) is activated during the active time section, the pull-up driver 123 may provide the core voltage (VCORE) to the pull-up power line (RTO). The pull-up driver 123 may include a PMOS transistor P10. The PMOS transistor P10 is coupled between the core voltage (VCORE) input terminal and the pull-up power line (RTO) so as to receive the pull-up drive signal (SAP2B) through a gate terminal.

If the pull-down drive signal (SAN1) is activated during the over-driving time section, the pull-down driver 124 may provide a ground voltage (VSS) to the pull-down power line (SB). The pull-down driver 124 may include an NMOS transistor N14. The NMOS transistor N14 may be coupled between the ground voltage (VSS) input terminal and the pull-down power line (SB) so as to receive a pull-down drive signal (SAN1) through a gate terminal.

If the pull-down drive signal (SAN2) is activated during the over-driving time section, the over-driving controller 130 may provide a back-bias voltage to the pull-down power line SB. The over-driving controller 130 may include an NMOS transistor N15. The NMOS transistor N15 may be coupled between the back-bias voltage (VBBW) input terminal and the pull-down power line (SB) so as to receive a pull-down drive signal (SAN2) through a gate terminal.

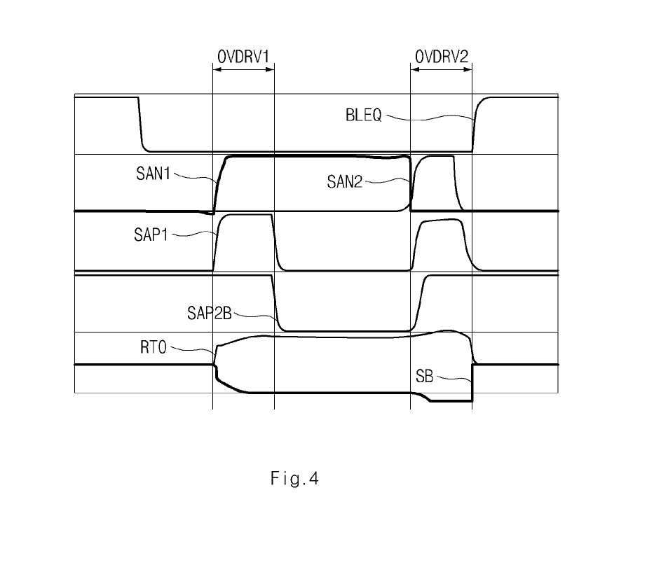

FIG. 4 is a timing diagram illustrating operations of the power-supply driving unit 120 and the over-driving controller 130 shown in FIG. 3.

Referring to FIGS. 1, 3, and 4, respective transistors of the precharge driver 121 are turned off in the active mode in which the precharge signal (BLEQ) is at a low level. Accordingly, the precharge voltage (VBLP) may not be applied to the pull-up power line (RTO) and the pull-down power line (SB).

The word line (WL) is activated after reception of the active command, and the semiconductor device may enter a first over-driving time section (OVDRV1) at a developing time of the pair of bit lines (BL, BLB). In the first over-driving time section (OVDRV1), the pull-down drive signal (SAN1), the pull-down drive signal (SAP1), and the pull-down drive signal (SAP2B) are at a high level, and the pull-down drive signal (SAN2) is at a low level.

In other words, if the pull-up drive signal (SAP1) is at a high level, the NMOS transistor N13 of the pull-up driver 122 is turned on. Accordingly, the pull-up power line (RTO) may be over-driven to the power-supply voltage (VDD) level. If the pull-down drive signal (SAN1) is at a high level, the NMOS transistor N14 of the pull-down driver 124 is turned on. Accordingly, the pull-down power line (SB) is over-driven to the ground voltage (VSS) level.

In this case, since the pull-up drive signal (SAP2B) is at a high level and the pull-down drive signal (SAN2) is at a low level in the first over-driving time section (OVDRV1), the pull-up driver 123 and the over-driving controller 130 may remain turned off.

In the active mode after lapse of the first over-driving time section (OVDRV1), the pull-up drive signal (SAP1) transitions to a low level so that the pull-up driver 122 is turned off. Since the pull-up drive signal (SAP2B) transitions to a low level, the pull-up driver 123 is turned on. Accordingly, the pull-up power line (RTO) is driven at the core voltage (VCORE) level during the active mode.

As described above, a voltage level of the pull-up power line (RTO) increases in the first over-driving time section (OVDRV1), and then slightly decreases to the core voltage (VCORE) level after lapse of the first over-driving time section (OVDRV1).

The word line WL may be activated before the precharge signal (BLEQ) transitions to a high level. If the precharge signal (BLEQ) transitions to a high level, the semiconductor device enters the precharge mode so that the word line WL is disabled.

That is, before the wordline (WL) disabled time is disabled prior to the precharge time section, a predetermined time section is used as a second over-driving time section. During the second over-driving time section (OVDRV2), the pull-down drive signal (SAN1) transitions to a low level, and the pull-up drive signal (SAP1), the pull-up drive signal (SAP2B), and the pull-down drive signal (SAN2) are at a high level.

If the pull-up drive signal (SAP1) is at a high level, the NMOS transistor N13 of the pull-up driver 122 is turned on. Accordingly, the pull-up power line (RTO) may be over-driven to the power-supply voltage (VDD) level. If the pull-down drive signal (SAN2) is at a high level, the NMOS transistor N15 of the over-driving controller 130 is turned on. Accordingly, the pull-down power line (SB) is over-driven to the back-bias voltage (VBBW) level.

In this case, since the pull-up drive signal (SAP2B) is at a high level and the pull-down drive signal (SAN1) is at a low level in the second over-driving time section (OVDRV2), the pull-up driver 123 and the pull-down driver 124 may remain turned off.

As described above, it can be recognized that a voltage level of the pull-up power line (RTO) increases in the second over-driving time section (OVDRV2), and the pull-up power line (RTO) is then precharged with the precharge voltage (VBLP) level after lapse of the second over-driving time section (OVDRV2). In addition, it can also be recognized that a voltage level of the pull-down power line (SB) decreases in the second over-driving time section (OVDRV2), and the pull-down power line (SB) is then precharged with the precharge voltage (VBLP) level after lapse of the second over-driving time section (OVDRV2).

Thereafter, assuming that the semiconductor device enters the precharge mode in which the precharge signal (BLEQ) transitions to a high level, NMOS transistors (N10˜N12) of the precharge driver 121 are turned on. Accordingly, the precharge voltage (VBLP) is applied to the pull-up power line (RTO) and the pull-down power line (SB) such that the semiconductor device is precharged with the precharge voltage (VBLP).

In other words, since the memory cell 300 is activated by the active command (ACTIVE CMD), the memory cell 300 may share electric charges with the true bit-line (BL). Assuming that low-level data is stored, a voltage level of the true bit-line (BL) decreases.

After that, the sense-amplifier 200 may sense and amplify a voltage difference (ΔV) of the bit-line pair (BL, BLB), such that the bit-line pair (BL, BLB) is driven at the power-supply voltage (VDD) and the ground voltage (VSS) level during the first over-driving time section (OVDRV1). In this case, the power-supply voltage (VDD) acting as the over-driving voltage is used to reduce the amplification time. Here, through the over-driving operation, a specific time (tRCD) ranging from the active command input time to the write command (WRITE CMD) input time can be reduced.

Upon receiving the data write command (WRITE CMD), high-level write data is applied to the bit-line pair (BL, BLB), such that voltage levels of a true bit-line (BL) and a false bit-line (BLB) are reversed. In this case, the sense-amplifier 200 may drive the true bit-line (BL) at the core voltage (VCORE), and may drive the false bit-line (BLB) at the ground voltage (VSS).

Thereafter, the bit-line pair (BL, BLB) may be driven at a back-bias voltage (VBBW) level during the second over-driving time section (OVDRV2). That is, until the memory cell 300 is deactivated in a time section prior to reception of the precharge command (PRECHARGE CMD), the true bit-line (BL) is driven at the power-supply voltage (VDD), and the false bit-line (BLB) is driven at the back-bias voltage (VBBW).

Through the over-driving operation, a specific time (tWR) ranging from the data write command (WRITE CMD) input time to the precharge command (PRECHARGE CMD) input time can be reduced. In addition, data is stored in the memory cell 300 at the back-bias voltage (VBBW) lower than the ground voltage (VSS) during the second over-driving time section (OVDRV2), such that refresh characteristics of data ‘0’ can be improved.

For reference, the true bit-line (BL) and the false bit-line (BLB) may be precharged, and an activation time of the precharge signal (BLEQ) serving as a control signal for precharging the pull-up power line (RTO) and the pull-down power line (SB) may be controlled through adjustment of the deactivation time of the memory cell 300 (i.e., the word line (WL) deactivation time).

As described above, the semiconductor device according to the embodiments may output data to the memory cell 300 not only at a drive voltage corresponding to data in the active mode but also at a drive voltage corresponding to data in the write mode. In addition, until the memory cell 300 is deactivated in the precharge mode, the memory cell 300 may receive data at an over-driving voltage higher or lower than the drive voltage.

That is, the sense-amplifier 200 may sense and amplify read data of the memory cell 300 through the bit-line pair (BL, BLB) in the active mode, and may output the amplified data to the memory cell 300 at a drive voltage corresponding to the read data. In addition, until the memory cell 300 is deactivated in the precharge mode, data is applied to the memory cell 300 at the over-driving voltage higher or lower than the drive voltage, resulting in improvement of a data retention time.

The sense-amplifier 200 may output data to the memory cell 300 at a drive voltage corresponding to the write data during the write mode. In addition, until the memory cell 300 is deactivated in the precharge mode, data may be applied to the memory cell 300 at the over-driving voltage higher or lower than the drive voltage. Accordingly, a data transmission time for the memory cell 300 and a data retention time can be improved.

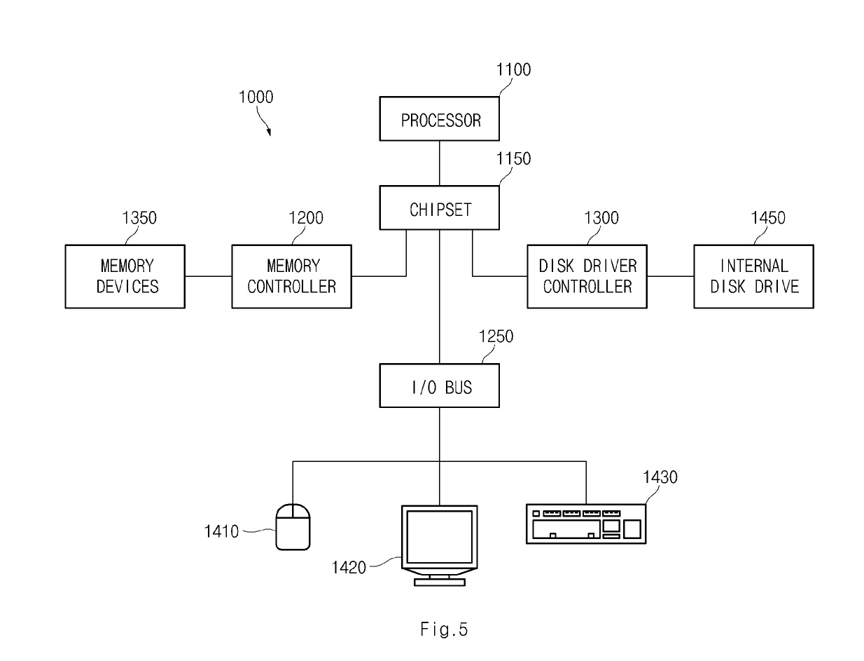

The semiconductor device discussed above is particularly useful in the design of memory devices, processors, and computer systems. For example, referring to FIG. 5, a block diagram of a system employing a semiconductor device in accordance with embodiments of the invention is illustrated and generally designated by a reference numeral 1000. The system 1000 may include one or more processors or central processing units (“CPUs”) 1100. The CPU 1100 may be used individually or in combination with other CPUs. While the CPU 1100 will be referred to primarily in the singular, it will be understood by those skilled in the art that a system with any number of physical or logical CPUs may be implemented.

A chipset 1150 may be operably coupled to the CPU 1100. The chipset 1150 is a communication pathway for signals between the CPU 1100 and other components of the system 1000, which may include a memory controller 1200, an input/output (“I/O”) bus 1250, and a disk drive controller 1300. Depending on the configuration of the system, any one of a number of different signals may be transmitted through the chipset 1150, and those skilled in the art will appreciate that the routing of the signals throughout the system 1000 can be readily adjusted without changing the underlying nature of the system.

As stated above, the memory controller 1200 may be operably coupled to the chipset 1150 and the memory devices 1350. In an embodiment, the memory devices 1350 may correspond to the sense amplifier 200 and memory cell 300 of FIG. 1, and the memory controller may correspond to the sense amplifier driving device 100 of FIG. 1. Thus, the memory controller 1200 can receive a request provided from the CPU 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may correspond to the semiconductor device 1 in FIG. 1, the semiconductor device 1 may include a plurality of word lines and a plurality of bit lines for defining a plurality of memory cell. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420 and 1430. The I/O devices 1410, 1420 and 1430 may include a mouse 1410, a video display 1420, or a keyboard 1430. The I/O bus 1250 may employ any one of a number of communications protocols to communicate with the I/O devices 1410, 1420, and 1430. Further, the I/O bus 1250 may be integrated into the chipset 1150.

The disk drive controller 1450 may also be operably coupled to the chipset 1150. The disk drive controller 1450 may serve as the communication pathway between the chipset 1150 and one or more internal disk drives 1450. The internal disk drive 1450 may facilitate disconnection of the external data storage devices by storing both instructions and data. The disk drive controller 1300 and the internal disk drives 1450 may communicate with each other or with the chipset 1150 using virtually any type of communication protocol, including all of those mentioned above with regard to the I/O bus 1250.

It is important to note that the system 1000 described above in relation to FIG. 5 is merely one example of a system employing a memory controller having function for selectively delaying address signals. In alternate embodiments, such as cellular phones or digital cameras, the components may differ from the embodiment shown in FIG. 5.

The above-mentioned description has disclosed a detailed explanation of the embodiments of the present invention. For reference, the embodiments may include additional structures for better understanding of the present invention as necessary although the additional structures are not directly associated with technical ideas of the present invention. In addition, the Active High or Active Low constructions for indicating deactivation states of a signal and circuit may be changed according to the embodiment. In order to implement the same function, a transistor structure may be modified as necessary. That is, the PMOS transistor and the NMOS transistor may be replaced with each other as necessary, and may be implemented using various transistors as necessary. In order to implement the same function, a logic gate structure may be modified as necessary. That is, a NAND operator, a NOR operator, etc. may be implemented using various combinations of a NAND gate, a NOR gate, an inverter, etc. The above-mentioned circuit modification may be very frequently generated, such that a very high number of cases may exist and associated modification can be easily appreciated by those skilled in the art, and as such a detailed description thereof will herein be omitted for convenience of description.

As is apparent from the above description, the semiconductor device including the sense-amplifier driving device according to the embodiments can improve a data retention time during which a memory cell can reliably maintain data.

The semiconductor device according to the embodiments stores data in a memory cell at a voltage lower than a ground voltage during an over-driving time, such that refresh characteristics of low data (i.e., data of 0) can be improved.

The semiconductor device according to the embodiments can increase a refresh time period, such that an access time of a memory cell is further increased, resulting in improvement of throughput of the semiconductor device.

Those skilled in the art will appreciate that the present invention may be carried out in other specific ways than those set forth herein without departing from the spirit and essential characteristics of the present invention. The above examples of the embodiments are therefore to be construed in all aspects as illustrative and not restrictive. The scope of the invention should be determined by the appended claims and their legal equivalents, not by the above description, and all changes coming within the meaning and equivalency range of the appended claims are intended to be embraced therein. Also, it is obvious to those skilled in the art that claims that are not explicitly cited in each other in the appended claims may be presented in combination as an example of an embodiment of the present invention or included as a new claim by a subsequent amendment after the application is filed.

Although a number of illustrative embodiments consistent with the invention have been described, it should be understood that numerous other modifications and embodiments can be devised by those skilled in the art that will fall within the spirit and scope of the principles of this disclosure. Particularly, numerous variations and modifications are possible in the component parts and/or arrangements which are within the scope of the disclosure, the drawings and the accompanying claims. In addition to variations and modifications in the component parts and/or arrangements, alternative uses will also be apparent to those skilled in the art.

What is claimed is:

1. A sense-amplifier driving device comprising:
a power-supply driving unit configured to respectively provide a first pull-up voltage and a first pull-down voltage to a pull-up power line and a pull-down power line during a first over-driving time section, and provide the first pull-up voltage to the pull-up power line during a second over-driving time section;
an over-driving controller configured to provide a second pull-down voltage lower than the first pull-down voltage to the pull-down power line during the second over-driving time section; and
a drive-signal generator configured to generate a drive signal activated for the first and second over-driving time sections so as to control driving of the power-supply driving unit.

2. The sense-amplifier driving device according to claim 1, wherein the first over-driving time section is a specific time section in which data is developed to a bit line of a memory cell after lapse of an active command.

3. The sense-amplifier driving device according to claim 1, wherein the second over-driving time section is a specific time section located before a disabled time of a word line of a memory cell, prior to beginning of a precharge time section.

4. The sense-amplifier driving device according to claim 1, wherein the first pull-up voltage is a power-supply voltage.

5. The sense-amplifier driving device according to claim 1, wherein the first pull-down voltage is a ground voltage.

6. The sense-amplifier driving device according to claim 1, wherein the second pull-down voltage is a back-bias voltage.

7. The sense-amplifier driving device according to claim 1, wherein the power-supply driving unit is configured to provide a second pull-up voltage lower than the first pull-up voltage to the pull-up power line during an active time section.

8. The sense-amplifier driving device according to claim 7, wherein the second pull-up voltage is a core voltage.

9. The sense-amplifier driving device according to claim 1, wherein the power-supply driving unit includes:
a first pull-up driver configured to generate the first pull-up voltage when a first pull-up drive signal is activated in the first over-driving time section and the second over-driving time section;
a second pull-up driver configured to provide a second pull-up voltage lower than the first pull-up voltage to the pull-up power line when a second pull-up drive signal is activated in the active time section; and
a first pull-down driver configured to provide the first pull-down voltage when a first pull-down drive signal is activated in the first over-driving time section.

10. The sense-amplifier driving device according to claim 1, wherein the over-driving controller includes a pull-down driving element which provides the second pull-down voltage when a second pull-down drive signal is activated in the second over-driving time section.

11. A semiconductor device comprising:
a memory cell in which a read or write operation of data is achieved;
a sense-amplifier configured to sense and amplify the data in response to a voltage applied to a pull-up power line and a pull-down power line; and
a sense-amplifier driving unit configured to provide a first pull-up voltage and a second pull-down voltage to the pull-up power line and the pull-down power line during a first over-driving time section, and configured to provide a second pull-down voltage lower than the first pull-up voltage and the first pull-down voltage to the pull-up power line and the pull-down power line during a second over-driving time section.

12. The semiconductor device according to claim 1, wherein the sense-amplifier driving unit includes:
a drive-signal generator configured to generate a drive signal activated for the first over-driving time section and the second over-driving time section; and
a power-supply driving unit configured to provide the first pull-up voltage and the first pull-down voltage during the first over-driving time section upon receiving the drive signal, and configured to provide the first pull-up voltage during the second over-driving time section; and
an over-driving controller configured to provide the second pull-down voltage to the pull-down power line during the second over-driving time section upon receiving the drive signal.

13. The semiconductor device according to claim 12, wherein the power-supply driving unit includes:
a first pull-up driver configured to generate the first pull-up voltage when a first pull-up drive signal is activated in the first over-driving time section and the second over-driving time section;
a second pull-up driver configured to provide a second pull-up voltage lower than the first pull-up voltage to the pull-up power line when a second pull-up drive signal is activated in the active time section; and
a first pull-down driver configured to provide the first pull-down voltage when a first pull-down drive signal is activated in the first over-driving time section.

14. The semiconductor device according to claim 1, wherein the over-driving controller includes a pull-down driving element which provides the second pull-down voltage when a second pull-down drive signal is activated in the second over-driving time section.

15. The semiconductor device according to claim 11, wherein the first over-driving time section is a specific time section in which data is developed to a bit line of a memory cell after lapse of an active command.

16. The semiconductor device according to claim 11, wherein the second over-driving time section is a specific time section located before a disabled time of a word line of the memory cell, prior to beginning of a precharge time section.

17. The semiconductor device according to claim 11, wherein the first pull-up voltage is a power-supply voltage.

18. The semiconductor device according to claim 11, wherein the first pull-down voltage is a ground voltage.

19. The semiconductor device according to claim 11, wherein the second pull-down voltage is a back-bias voltage.

20. The semiconductor device according to claim 11, wherein the power-supply driving unit is configured to provide a second pull-up voltage lower than the first pull-up voltage to the pull-up power line during an active time section.

21. The semiconductor device according to claim 20, wherein the second pull-up voltage is a core voltage.

22. A sense-amplifier driving device comprising:
an over-driving controller configured to provide a pull-down voltage lower than a ground voltage to a pull-down power line of a sense-amplifier when a pull-down drive signal is activated in an over-driving time section; and
a drive-signal generator configured to generate the pull-down drive signal activated for the over-driving time section so as to control driving of the over-driving controller.

23. The sense-amplifier driving device according to claim 22, wherein the over-driving time section is a specific time section located before a disabled time of a word line of a memory cell, prior to beginning of a precharge time section.

24. The sense-amplifier driving device according to claim 22, wherein the pull-down voltage is a back-bias voltage.

25. A system comprising:
a processor;
a memory controller configured to receive a request and data from the processor; and
a memory device configured to receive a memory controller request and the data from the memory controller,
wherein the memory device includes a sense-amplifier driving device comprising:
a power-supply driving unit configured to respectively provide a first pull-up voltage and a first pull-down voltage to a pull-up power line and a pull-down power line during a first over-driving time section, and provide the first pull-up voltage to the pull-up power line during a second over-driving time section;
an over-driving controller configured to provide a second pull-down voltage lower than the first pull-down voltage to the pull-down power line during the second over-driving time section; and
a drive-signal generator configured to generate a drive signal activated for the first and second over-driving time sections so as to control driving of the power-supply driving unit.

26. A system comprising:
a processor;
a chipset configured to couple with the processor;
a controller configured to receive a request provided from the processor through the chipset;
a memory device configured to receive a memory controller request and the data from the controller; and
an I/O device configured to couple with the chipset,
wherein the memory device includes a sense-amplifier driving device comprising:
a power-supply driving unit configured to respectively provide a first pull-up voltage and a first pull-down voltage to a pull-up power line and a pull-down power line during a first over-driving time section, and provide the first pull-up voltage to the pull-up power line during a second over-driving time section;
an over-driving controller configured to provide a second pull-down voltage lower than the first pull-down voltage to the pull-down power line during the second over-driving time section; and
a drive-signal generator configured to generate a drive signal activated for the first and second over-driving time sections so as to control driving of the power-supply driving unit.
